(19) United States
(12) Patent Application Publication
(10) Pub. No.: US 2026/0101536 A1
(43) Pub. Date: Apr. 9, 2026

(54) TRANSISTOR STRUCTURE OF TRANSISTORS WITH SHARED GATE

(71) Applicant: INTERNATIONAL BUSINESS MACHINES CORPORATION, ARMONK, NY (US)

(72) Inventors: HUIMEI ZHOU, Albany, NY (US); Dechao Guo, Albany, NY (US); Huiming Bu, Glenmont, NY (US)

(21) Appl. No.: 18/905,221

(22) Filed: Oct. 3, 2024

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 84/0128; H10D 84/0135; H10D 84/0144; H10D 84/038; H10D 84/83

(57) ABSTRACT

A transistor structure and a method of forming the transistor structure. The transistor structure includes an upper transistor and a lower transistor. The upper transistor includes a gate. The gate includes a lower portion and an upper portion. The lower transistor includes the lower portion of the gate and does not include the upper portion of the gate. The method of forming the transistor structure includes forming the upper transistor and the lower transistor, where the upper transistor includes the gate, where the gate includes a lower portion and an upper portion, and where the lower transistor includes the lower portion of the gate and does not include the upper portion of the gate.

### BACKGROUND

The present invention relates to a transistor structure, and more specifically, to a transistor structure of transistors with a shared gate.

### SUMMARY

Embodiments of the present invention provide a transistor structure. The transistor structure comprises: an upper transistor comprising a gate, wherein the gate comprises a lower portion and an upper portion; and a lower transistor comprising the lower portion of the gate and not comprising the upper portion of the gate.

Embodiments of the present invention provide method of forming a transistor structure. The method comprises: forming an upper transistor and a lower transistor. The upper transistor comprises a gate. The gate comprises a lower portion and an upper portion. The lower transistor comprises the lower portion of the gate and does not comprise the upper portion of the gate.

### BRIEF DESCRIPTION OF THE DRAWINGS

FIG. 1 depicts a three-dimensional view of an intermediate state of a structure that includes an epitaxial wafer, a trench, a dummy gate, and a dielectric film, in accordance with embodiments of the present invention.

FIGS. 2A, 2B, and 2C depict an X view, a Y1 view, and a Y2 view, respectively, in the intermediate state of the structure in FIG. 1, in accordance with embodiments of the present invention.

FIGS. 3A, 3B, and 3C depict FIGS. 2A, 2B, and 2C, respectively, after an upper spacer has been deposited on a sidewall of the dummy gate, in accordance with embodiments of the present invention.

FIGS. 4A, 4B, and 4C depict FIGS, 3A, 3B, and 3C, respectively, after portions of layers of the epitaxial wafer have been etched away via an etch process, in accordance with embodiments of the present invention.

FIGS. 5A, 5B, and 5C depict FIGS. 4A, 4B, and 4C, respectively, after deposition, via a deposition process, of an inner spacer in spaces created by an etching away of first and second high percent SiGe layers, in accordance with embodiments of the present invention.

FIGS. 6A, 6B, and 6C depict FIGS. 5A, 5B, and 5C, respectively, after a portion of a low percent SiGe layer beneath the inner spacer has been etched away and after a first insulating layer has been deposited on a first monocrystalline Si layer, in accordance with embodiments of the present invention.

FIGS. 7A, 7B, and 7C depict FIGS. 6A, 6B, and 6C, respectively, after epitaxial layers have been formed on a dielectric layer, in accordance with embodiments of the present invention.

FIGS. 8A, 8B, and 8C depict FIGS. 7A, 7B, and 7C, respectively, after an interlevel dielectric (ILD) layer has been deposited on the epitaxial layers, in accordance with embodiments of the present invention.

FIGS. 9A, 9B, and 9C depict FIGS. 8A, 8B, and 8C, respectively, after removal of the dummy gate, the high percent SiGe layers, and portions of the dielectric film, in accordance with embodiments of the present invention.

FIGS. 10A, 10B, and 10C depict FIGS. 9A, 9B, and 9C, respectively, after a gate has replaced the dummy gate, in accordance with embodiments of the present invention.

FIG. 10D depicts the gate in more detail, in accordance with embodiments of the present invention.

FIGS. 11A, 11B, and 11C depict FIGS. 10A, 10B, and 10C, respectively, after conductive contacts have been formed within the ILD layer and after a back end of line (BEOL) wiring has been formed on the top surfaces of the gate, the upper spacer, and the ILD layer, in accordance with embodiments of the present invention.

FIGS. 12A, 12B, and 12C depict FIGS. 11A, 11B, and 11C, respectively, after the first monocrystalline Si layer and the low percent SiGe layer have been removed and after the BEOL wiring and a carrier wafer have been coupled together, in accordance with embodiments of the present invention.

FIGS. 13A, 13B, and 13C depict FIGS. 12A, 12B, and 12C, respectively, after a channel has been formed under the first insulating layer and the gate, in accordance with embodiments of the present invention.

FIGS. 14A, 14B, and 14C depict FIGS. 13A, 13B, and 13C, respectively, after a lower portion of the channel has been removed, in accordance with embodiments of the present invention.

FIGS. 15A, 15B, and 15C depict FIGS. 14A, 14B, and 14C, respectively, after a second insulating layer has been formed under, and in direct mechanical contact with, the channel, in accordance with embodiments of the present invention.

FIGS. 16A, 16B, and 16C depict FIGS. 15A, 15B, and 15C, respectively, after backside contacts have been formed within the second insulating layer, in accordance with embodiments of the present invention.

FIG. 17A depicts an X view of a transistor structure, in accordance with embodiments of the present invention.

FIGS. 17B and 17C depict alternative transistor structures, in accordance with embodiments of the present invention

FIGS. 18A, 18B, 18C, and 18D depict intermediate structures, in accordance with embodiments of the present invention.

### DETAILED DESCRIPTION

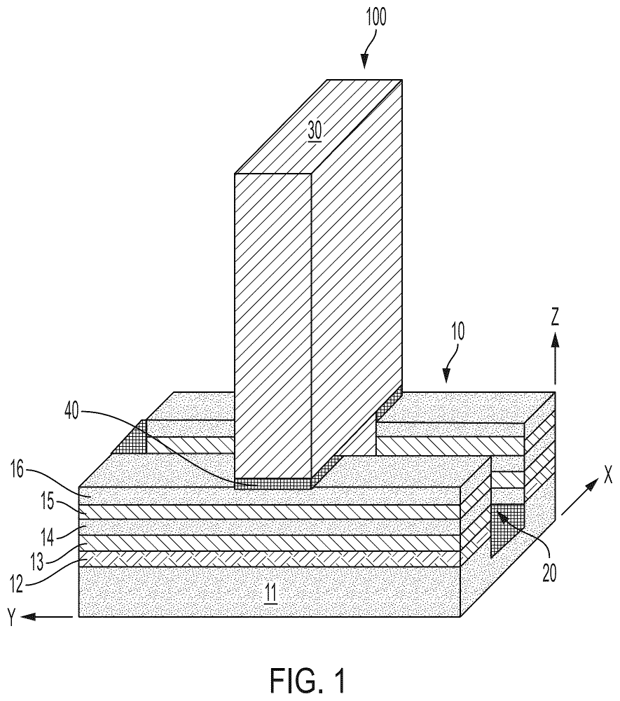

FIG. 1 depicts a three-dimensional view of an intermediate state of a structure 100 that includes an epitaxial wafer 10, a trench 20, a dummy gate 30, and a dielectric film 40, in accordance with embodiments of the present invention.

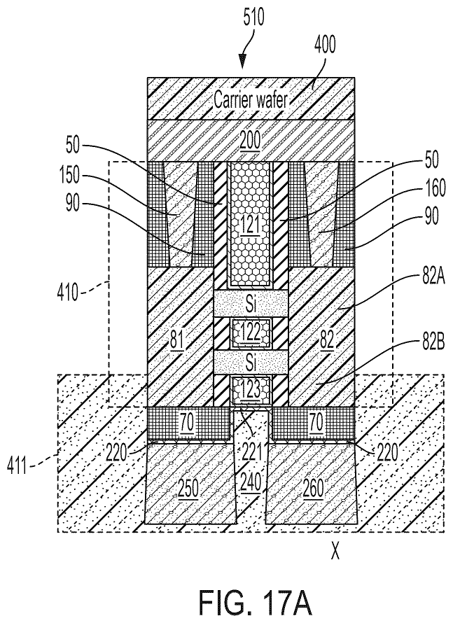

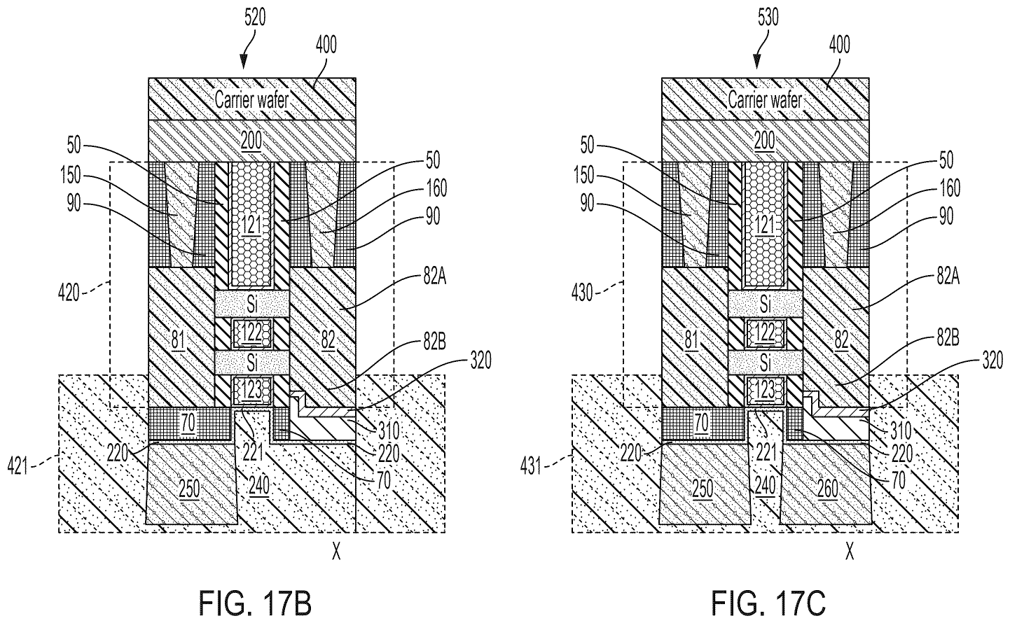

In one embodiment, a final form of the structure 100 is a transistor structure (see transistor structures 510, 520 and 530 in FIGS. 17A, 17B and 17C, respectively). FIG. 1 depicts reference orthogonal directions X, Y and Z.

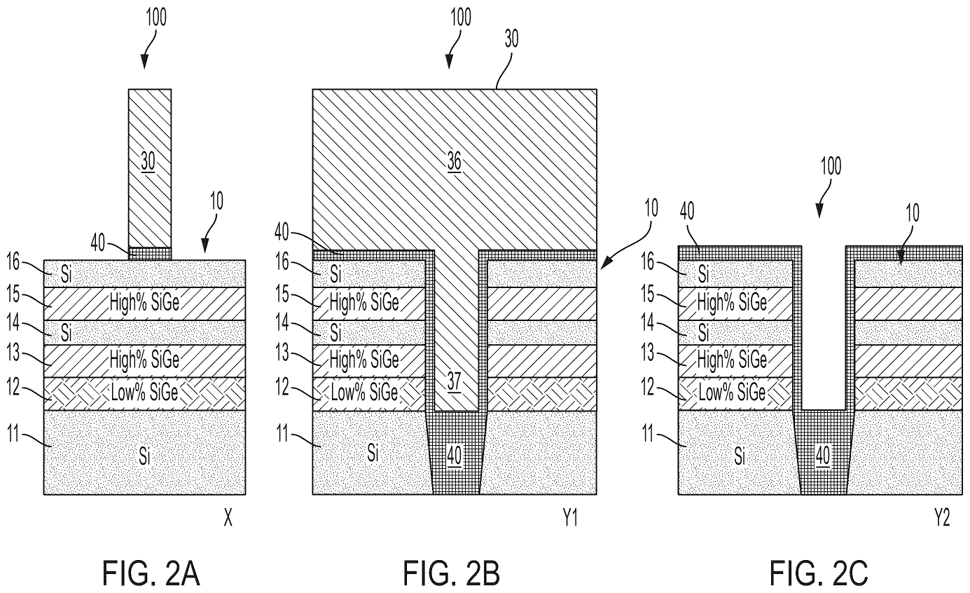

FIGS. 2A, 2B, and 2C depict an X view, a Y1 view, and a Y2 view, respectively, in the intermediate state of the structure 100 in FIG. 1, in accordance with embodiments of the present invention.

The X view is a cross-sectional view of a plane that slices through the epitaxial wafer 10 and the dummy gate 30, wherein a line normal to the plane of the X view is oriented in the direction X.

The Y1 view is a cross-sectional view of a plane that slices through the epitaxial wafer 10 and the dummy gate 30, wherein a line normal to the plane of the Y1 view is oriented in the direction Y.

The Y2 view is a cross-sectional view of a plane that slices through the epitaxial wafer 10 and does not slice through the dummy gate 30, wherein a line normal to the plane of the Y2 view is oriented in the direction Y.

The preceding description of the X, Y1, and Y2 views are applicable to all Figures presented herein.

The epitaxial wafer 10 includes layers 11-16 sequentially stacked in the Z direction.

Layer 11 is a first monocrystalline silicon (Si) layer.

Layer 12 is a low percent silicon germanium (SiGe) layer.

Layer 13 is a first high percent SiGe layer.

Layer 14 is a second monocrystalline Si layer.

Layer 15 is a second high percent SiGe layer.

Layer 16 is a third monocrystalline Si layer.

Layers 12, 13 and 15 are each a SiGe layer structured as Si₁₋ₓGeₓ, wherein x is a real number in a range of 0<x<1.

In the low percent SiGe layer 12, x=x_{low}, wherein x_{low} is in a range of 0.05≤x_{low}≤0.20.

In the first high percent SiGe layer 13, x=x_{high1}, wherein x_{high1}>x_{low}+0.15.

In the second high percent SiGe layer 15, x=x_{high2}, wherein x_{high2}>x_{low}+0.15.

In one embodiment, x_{high1}=x_{high2}.

In one embodiment, x_{high1}≠x_{high2}.

In one embodiment, the dummy gate 30 comprises polysilicon.

In one embodiment, the dielectric film 40 comprises silicon dioxide (SiO₂).

A top portion 36 of the dummy gate 30 is above, and in direct mechanical contact with, the dielectric film 40.

A bottom portion 37 of the dummy gate 30 is surrounded by layers 12-16 of the epitaxial wafer 10.

A portion of the dielectric film 40 is above, and in direct mechanical contact with, the third monocrystalline Si layer 16.

The first monocrystalline Si layer 11 surrounds, and is in direct mechanical contact with, a bottom portion of the dielectric film 40 within the trench 20.

The structure 100 in FIGS. 1 and 2A-2C may be formed as follows.

The epitaxial wafer 10 is formed by any process known in the art for forming an epitaxial wafer such as, inter alia, a conventional epitaxial sheet growth process.

Then, the trench 20 is formed in the epitaxial wafer 10 by an etch process such as, inter alia, a dry etch process.

Then, the dielectric film dielectric film 40 is formed above the epitaxial wafer 10 and within the trench 20 by a deposition process such as, inter alia, chemical vapor deposition (CVD), physical vapor deposition (PVD), High Aspect Ratio Process (HARP), etc.

After the dielectric film 40 is formed, the dummy gate 30 is formed on the dielectric film 40, and within the trench 20, by a deposition process such as, inter alia, chemical vapor deposition (CVD).

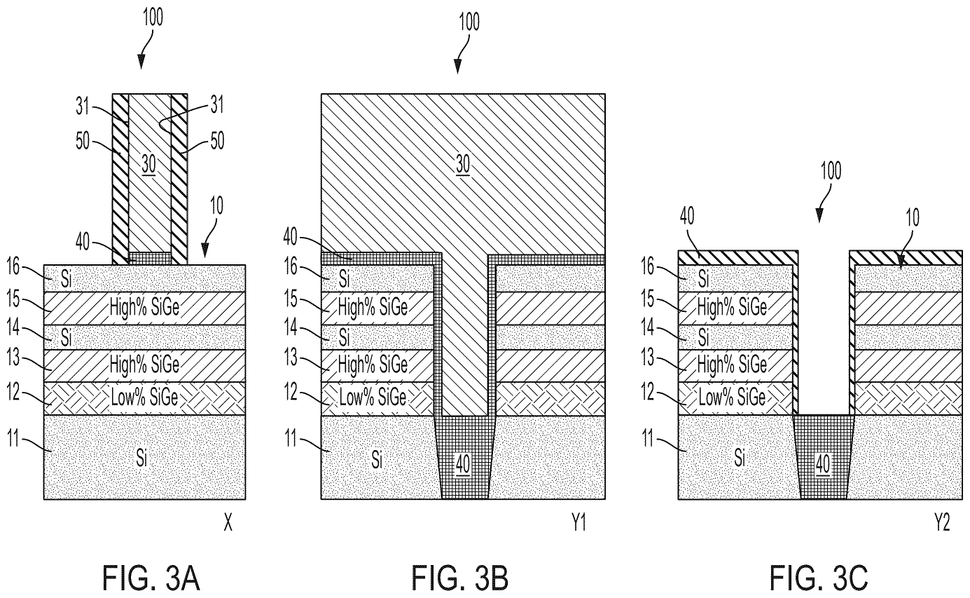

FIGS. 3A, 3B, and 3C depict FIGS. 2A, 2B, and 2C, respectively, after an upper spacer 50 has been deposited on a sidewall 31 of the dummy gate 30, in accordance with embodiments of the present invention.

The upper spacer 50 comprises a nitride such as, inter alia, SiN, SiBCN, SiCN, etc.

The upper spacer 50 may be deposited on the sidewall 31 of the dummy gate 30 via, inter alia, atomic layer deposition (ALD),

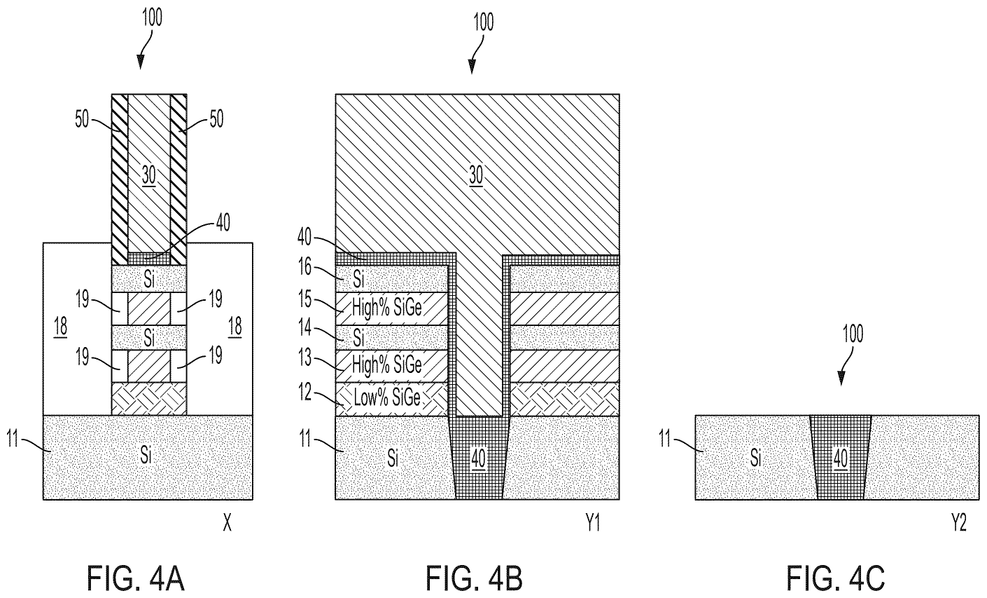

FIGS. 4A, 4B, and 4C depict FIGS, 3A, 3B, and 3C, respectively, after portions of layers 12-16 of the epitaxial wafer 10 have been etched away via an etch process, in accordance with embodiments of the present invention. Spaces 18 and 19 are where the portion of layers 12-16 existed before being etched away. More specifically, spaces 19 are where portions of first and second high percent SiGe layer 13 and 15, respectively, existed before being etched away.

The etch process that etched away the portions of layers 12-16 may be, inter alia, a dry etch, a wet etch, a laser etch, an ion beam etch, etc.

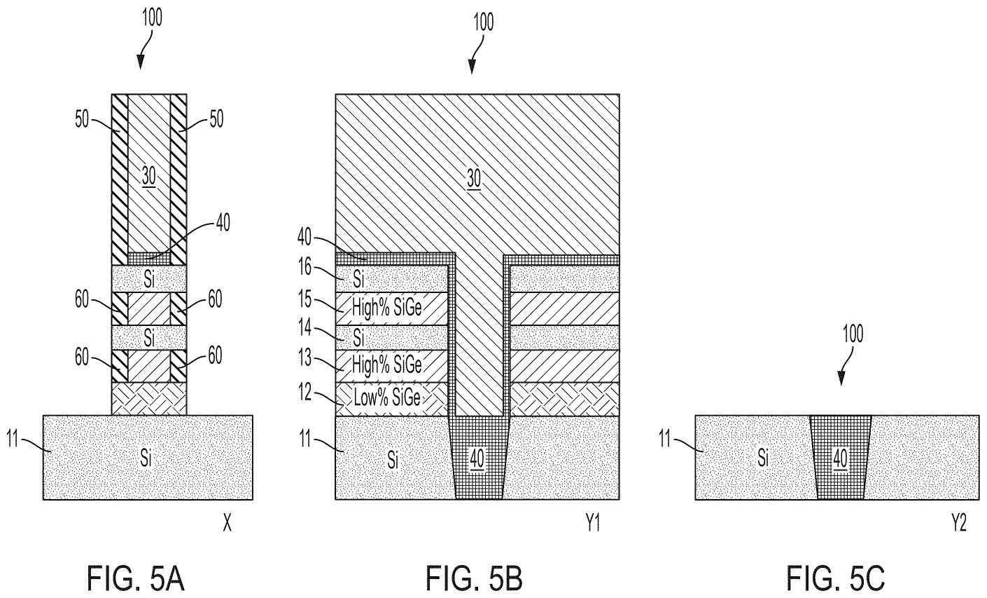

FIGS. 5A, 5B, and 5C depict FIGS. 4A, 4B, and 4C, respectively, after deposition, via a deposition process and etch back, of an inner spacer 60 in the spaces 19 (see FIG. 4A) created by an etching away of the first and second high percent SiGe layers 13 and 15, respectively, in accordance with embodiments of the present invention.

The inner spacer 60 comprises a nitride such as, inter alia, SiN, SiBCN, SiCN, etc.

The deposition process for depositing the inner spacer 60 may be, inter alia, atomic layer deposition (ALD), flowable chemical vapor deposition (FCVD), etc.

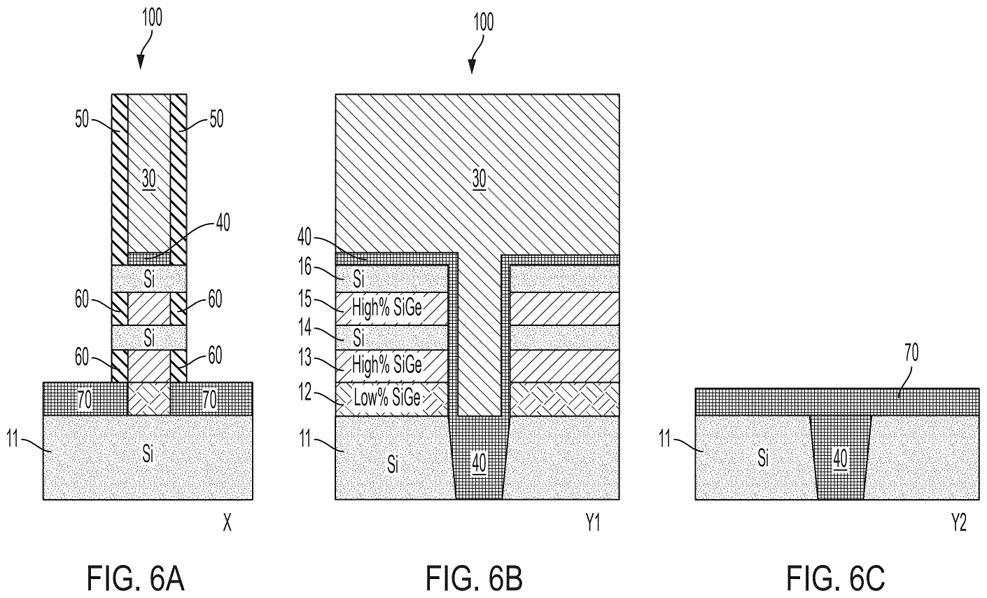

FIGS. 6A, 6B, and 6C depict FIGS. 5A, 5B, and 5C, respectively, after a portion of the low percent SiGe layer 12 beneath the inner spacer 60 has been etched away and after a first insulating layer 70 has been deposited on the first monocrystalline Si layer 11, in accordance with embodiments of the present invention.

The first insulating layer 70 surrounds, and is in direct mechanical contact with, the remaining low percent SiGe layer 12. In one embodiment, the first insulating layer 70 has a height in the direction Z equal to the height of the low percent SiGe layer 12.

In one embodiment, the first insulating layer 70 comprises a dielectric material such as, inter alia, silicon dioxide (SiO₂).

The first insulating layer 70 may be formed by a deposition process such as, inter alia, chemical vapor deposition (CVD), physical vapor deposition (PVD), High Aspect Ratio Process (HARP), etc.

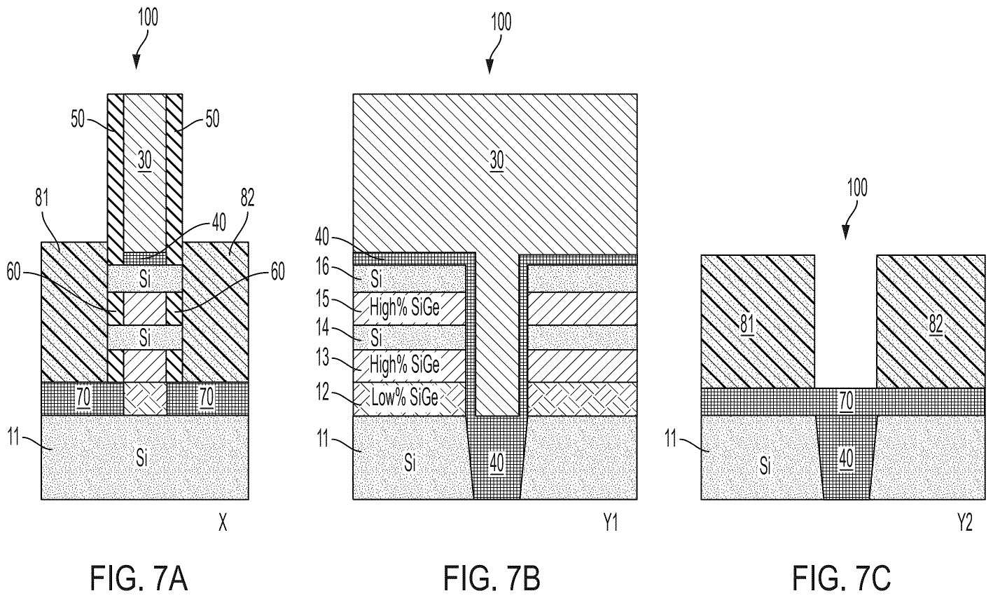

FIGS. 7A, 7B, and 7C depict FIGS. 6A, 6B, and 6C, respectively, after epitaxial layers 81 and 82 have been formed on the dielectric layer 70, in accordance with embodiments of the present invention.

The epitaxial layers 81 and 82 are in direct mechanical contact with the dielectric layer 70, the inner spacer 60, the second monocrystalline Si layer 14, the third monocrystalline Si layer 16, and the upper spacer 50.

In one embodiment, the epitaxial layers 81 and 82 extend higher in the Z direction than the dielectric film 40.

The epitaxial layers 81 and 82 will be used as a source and a drain, or a drain and a source, respectively, of an NMOS Field Effect Transistor (NFET) or a PMOS Field Effect Transistor (PFET).

If an NFET is to be formed, the epitaxial layers 81 and 82 may comprise n-type dopants such as, inter alia, phosphorus (P), arsenic (As), Antimony (Sb), etc.

If a PFET is to be formed, the epitaxial layers 81 and 82 may comprise p-type dopants such as, inter alia, boron (B), boron fluoride (BF), gallium (Ga), indium (In), etc.

The epitaxial layers 81 and 82 may be formed, inter alia, by a conventional epitaxial sheet growth process.

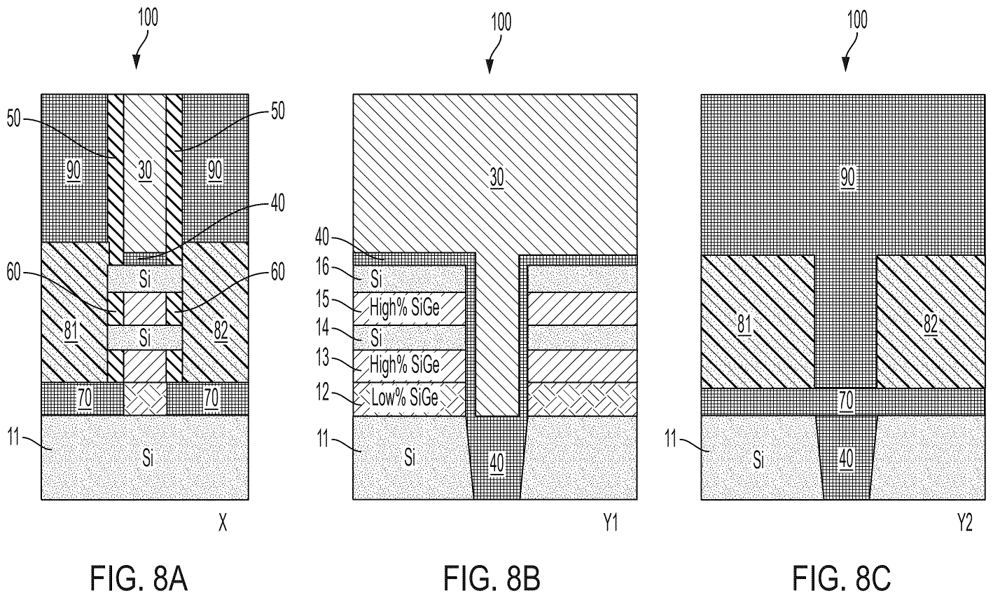

FIGS. 8A, 8B, and 8C depict FIGS. 7A, 7B, and 7C, respectively, after an interlevel dielectric (ILD) layer 90 has been deposited on the epitaxial layers 81 and 82, in accordance with embodiments of the present invention.

The ILD layer 90 comprises an oxide of silicon such as, inter alia, SiO₂, SiOC, etc., and may be formed by, inter alia, flowable chemical vapor deposition (FCVD).

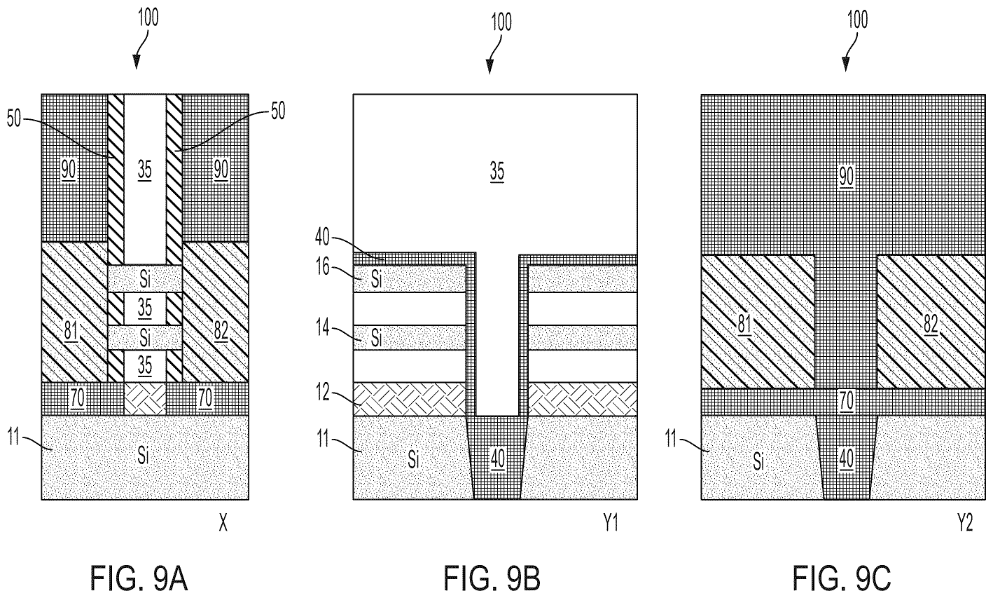

FIGS. 9A, 9B, and 9C depict FIGS. 8A, 8B, and 8C, respectively, after removal of: the dummy gate 50, the first high percent SiGe layer 13, the second high percent SiGe layer 15, and portions of the dielectric film 40, in accordance with embodiments of the present invention.

The spaces 35 are where the dummy gate 50, the first high percent SiGe layer 13, and the second high percent SiGe layer 15 existed before being removed.

The dummy gate 50 is removed by a poly pull process which may be implemented using, inter alia, a dry etch process.

The first high percent SiGe layer 13 and the second high percent SiGe layer 15 are removed by a channel release process which may be implemented using, inter alia, a dry etch process.

The portions of the dielectric film 40 are removed by an etch process such as, inter alia, a wet etch process, a dry etch process, etc.

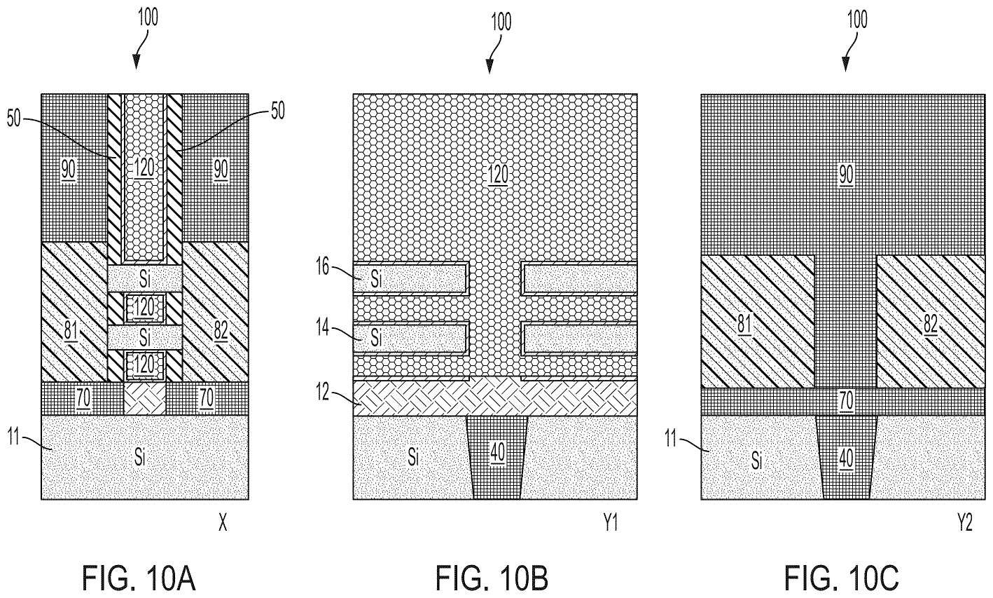

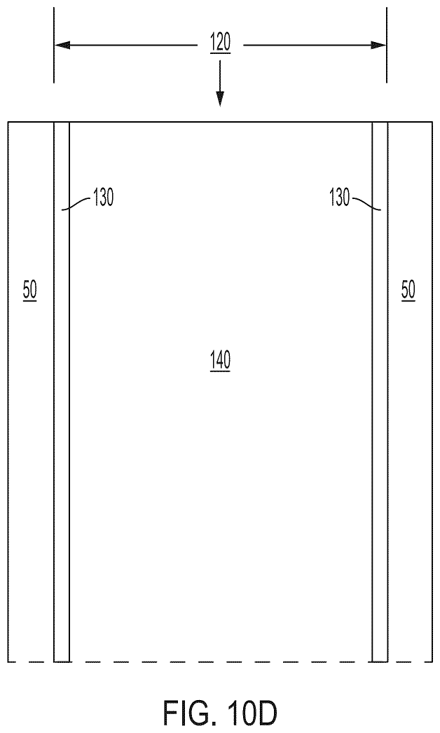

FIGS. 10A, 10B, and 10C depict FIGS. 9A, 9B, and 9C, respectively, after a gate 120 has replaced the dummy gate 50, in accordance with embodiments of the present invention.

The gate 120 is above (in the direction Z), and in direct mechanical contact with, and the third monocrystalline Si layer 16.

The gate 120 is within, and in direct mechanical contact with, the upper spacer 50.

In one embodiment, the top surfaces (i.e., highest surfaces in the Z direction) of the gate 120, the spacer 50, and the ILD layer 90 are coplanar.

FIG. 10D depicts the gate 120 in more detail, in accordance with embodiments of the present invention.

The gate 120 comprises a high-k liner 130 and a metal gate 140.

The high-k liner 130 comprises a high dielectric constant (k) material in comparison with the dielectric constant of silicon dioxide (SiO₂). The dielectric constant (k) and the permittivity (ϵ) of a material are related via ϵ=k*ϵ₀, where ϵ₀ is a vacuum permittivity having a constant value of 8.854*10⁻¹² farad per meter. Thus, a high-k material has a higher dielectric constant and a higher permittivity than SiO₂.

The high-k material in the high-k liner 30 may include, inter alia, HfO₂, Al₂O₃, etc.

The metal gate 140 comprises a work function material such as, inter alia, TiN, AlN, etc.

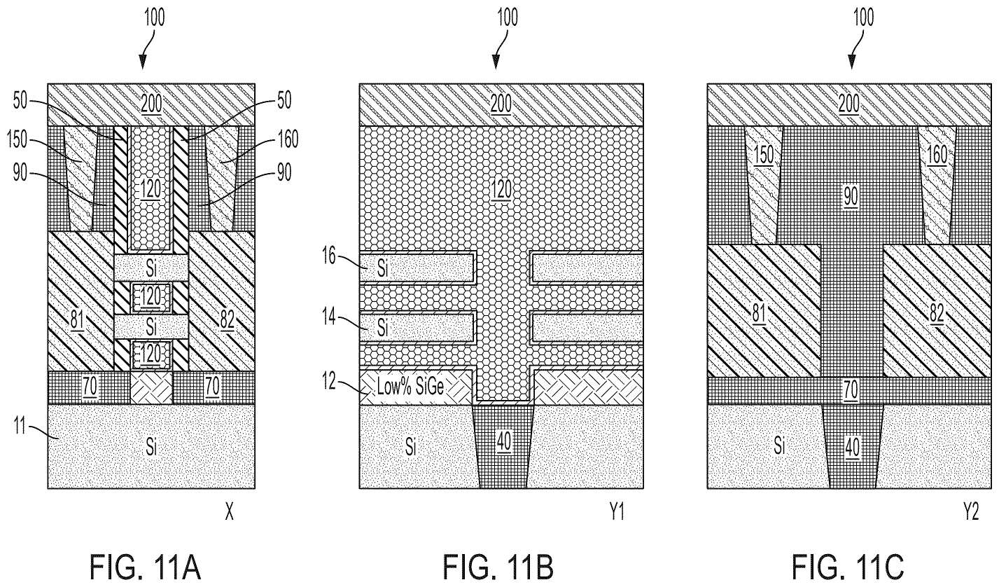

FIGS. 11A, 11B, and 11C depict FIGS. 10A, 10B, and 10C, respectively, after source/drain contacts 150 and 160, which are conductive contacts, have been formed within the ILD layer 90 and after a back end of line (BEOL) wiring 200 has been formed on the top surfaces of the gate 120, the upper spacer 50, and the ILD layer 90, in accordance with embodiments of the present invention.

The source/drain contacts 150 and 160, which may include a conductive material such as, inter alia, tungsten (W), cobalt (Co), etc., are in direct contact with the epitaxial layers 81 and 82, respectively.

The source/drain contacts 150 and 160 may be formed by etching a portion of the ILD layer 90 (e.g., by dry etch, wet etch, etc.) to form an opening within the ILD layer 90, followed by filling the opening with the conductive material (e.g., by chemical vapor deposition (CVD), physical vapor deposition (PVD), etc.)

The BEOL wiring 200 comprises alternating metal layers and insulator layers.

The metal layers may comprise, inter alia, copper (Cu), tungsten (W), aluminum (Al), etc.

The insulator layers may comprise, inter alia, silicon dioxide, carbon doped oxides (e.g., SiCOH), etc.

The BEOL wiring 200 may be formed, layer by layer, via techniques known in the art.

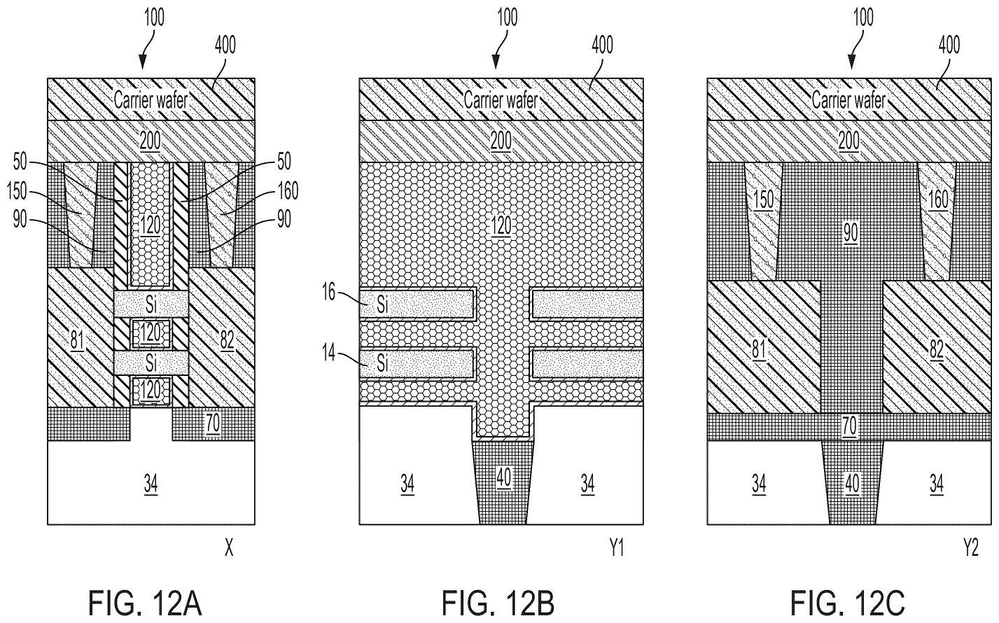

FIGS. 12A, 12B, and 12C depict FIGS. 11A, 11B, and 11C, respectively, after the first monocrystalline Si layer 11 and the low percent SiGe layer 12 have been removed and after the BEOL wiring 200 and a carrier wafer 400 have been coupled together, in accordance with embodiments of the present invention.

The first monocrystalline Si layer 11 and the low percent SiGe layer 12 may be removed by, inter alia, a dry etch process.

The BEOL wiring 200 and the carrier wafer 400 can be coupled together before, after, or simultaneous with the removal of the first monocrystalline Si layer.

The spaces 34 are where the first monocrystalline Si layer 11 and the low percent SiGe layer 12 existed before being removed.

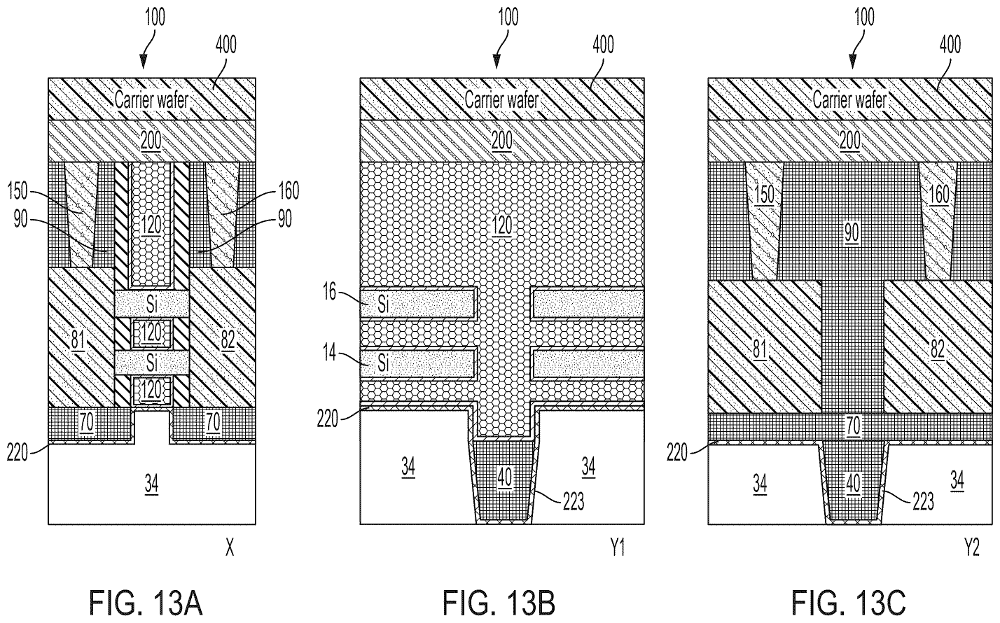

FIGS. 13A, 13B, and 13C depict FIGS. 12A, 12B, and 12C, respectively, after a channel 220 has been formed under the first insulating layer 70 and the gate 120, in accordance with embodiments of the present invention.

The channel 220 comprises a lower portion 223 (see FIG. 13B).

The channel 220 comprises a channel material which may be, inter alia, such a semiconducting material (e.g., indium gallium zinc oxide (IGZO), indium gallium tin oxide (IGTO), etc.).

The channel 220 may be formed via, inter alia, by chemical vapor deposition (CVD), physical vapor deposition (PVD), atomic layer deposition (ALD), etc.

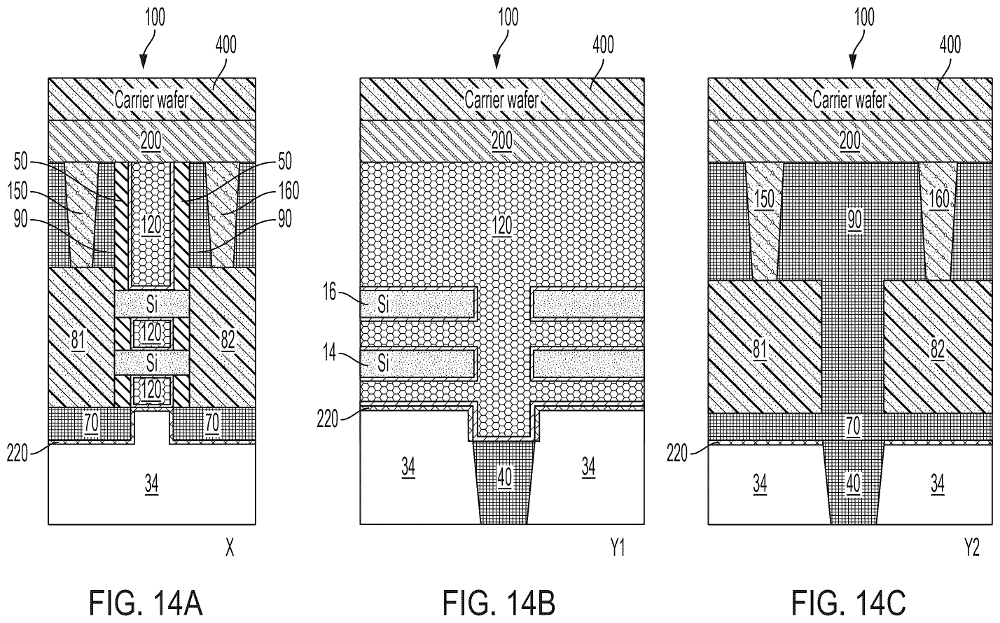

FIGS. 14A, 14B, and 14C depict FIGS. 13A, 13B, and 13C, respectively, after the lower portion 223 of the channel 220 has been removed, in accordance with embodiments of the present invention.

The lower portion 223 of the channel 220 may be removed via, inter alia, wet etching, dry etching, etc.

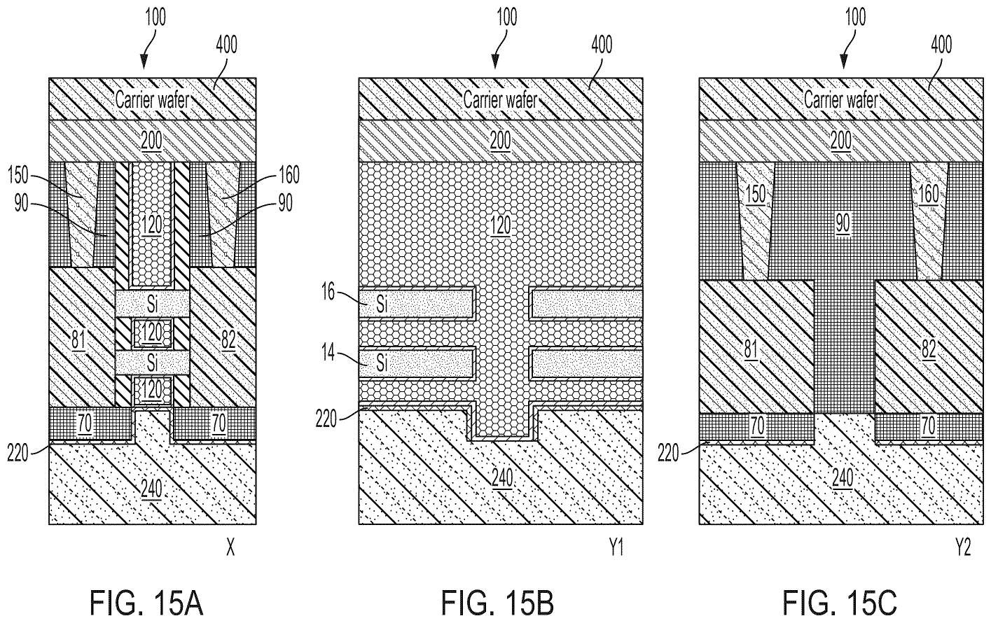

FIGS. 15A, 15B, and 15C depict FIGS. 14A, 14B, and 14C, respectively, after a second insulating layer 240 has been formed under, and in direct mechanical contact with, the channel 220, in accordance with embodiments of the present invention.

In one embodiment, the first insulating layer 240 comprises a dielectric material such as, inter alia, silicon dioxide (SiO₂).

The second insulating layer 240 may be formed by a deposition process such as, inter alia, chemical vapor deposition (CVD), physical vapor deposition (PVD), atomic layer deposition (ALD), etc.

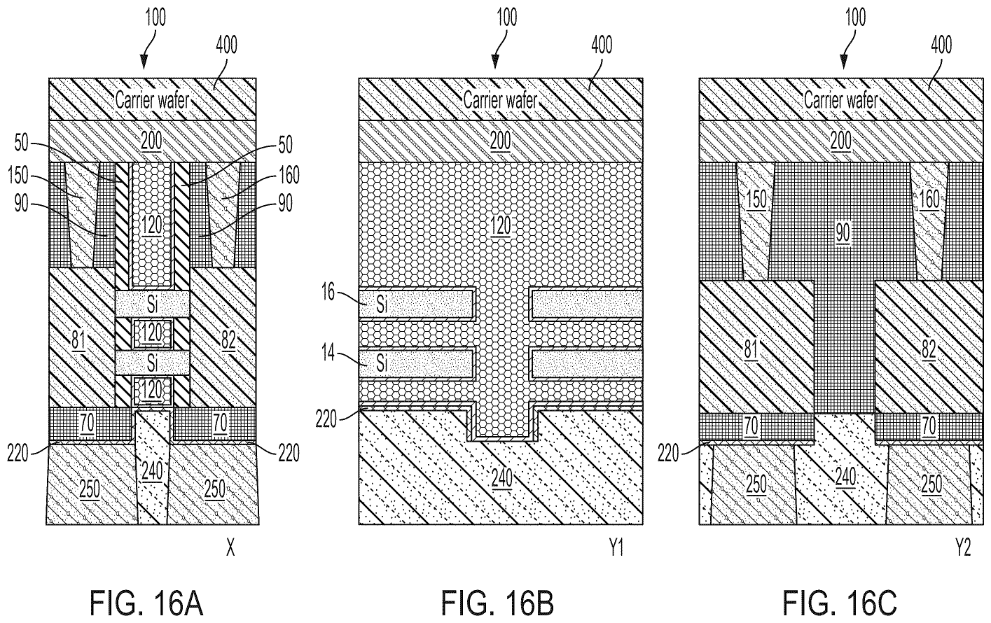

FIGS. 16A, 16B, and 16C depict FIGS. 15A, 15B, and 15C, respectively, after backside contacts 250 and 260 have been formed within the second insulating layer 240, in accordance with embodiments of the present invention. In FIGS. 16A, 16B, and 16C, the structure 100 is a final structure that is called a transistor structure.

The backside contacts 250 and 260 may comprise a conducting material such as, inter alia, tungsten (W), cobalt (Co), copper (Cu), ruthenium (Ru), etc.

The backside contacts 250 and 260 may be formed by etching a portion of the second insulating layer 240 (e.g., by dry etch, wet etch, etc.) to form an opening within the second insulating layer 240, followed by filling the opening with the conductive material (e.g., by chemical vapor deposition (CVD), physical vapor deposition (PVD), etc.).

FIG. 17A depicts an X view of a transistor structure 510, in accordance with embodiments of the present invention.

The transistor structure 510 is the structure 100 in FIGS. 16A-16C and is a final structure of the structure 100, and the X view of the transistor structure 510 is the X view of structure 100 in FIG. 16A.

The transistor structure 510, which is the same structure as structure 100 in FIG. 16A, includes an upper transistor 410 and a lower transistor 411.

The upper transistor 410, which is a nanosheet (NS) transistor in one embodiment, comprises: (i) a source/drain, namely the epitaxial layer 81; (ii) a source/drain, namely the epitaxial layer 82; and (iii) a gate, namely the gate 120.

The gate 120 comprises upper portions 121 and 122, and a lower portion 123.

The lower transistor 411, which is a two-dimensional (2D) transistor in one embodiment, comprises: (i) the backside contact 250; (ii) the backside contact 260; and (iii) a gate, namely the lower portion 123 of the gate 120. Thus, the gate 120 is a shared gate that is shared by the upper transistor 410 and the lower transistor 411.

FIGS. 17B and 17C depict alternative transistor structures 520 and 530, respectively, in accordance with embodiments of the present invention.

The transistor structure 520 in FIG. 17B includes an upper transistor 420 and a lower transistor 421 which are analogous to upper transistor 410 and a lower transistor 411, respectively, in the transistor structure 510 in FIG. 17A.

The transistor structure 520 differs from transistor structure 510 in that the transistor structure 520: does not include the backside contact 260, includes a metal liner 310 above and in direct mechanical contact with the channel 220, and includes a silicide layer 320 above and in direct mechanical contact with the metal liner 310.

The metal liner 310 may include, inter alia, titanium nitride (TiN) and may be formed via, inter alia, chemical vapor deposition (CVD), atomic layer deposition (ALD), etc.

The silicide layer 320 comprises a silicide such as, inter alia, TiSiₓ (x=1, 2, . . . ) and may be formed via, inter alia, a metal deposition and anneal process.

In transistor structure 520, the metal liner 310 is disposed between, and is in direct mechanical contact with, the channel 220 and the silicide layer 320. The silicide layer 320 is disposed between, and is in direct mechanical contact with, the metal liner 310 and a bottom surface of the epitaxial layer 82.

The transistor structure 530 in FIG. 17C includes an upper transistor 430 and a lower transistor 431 which are analogous to upper transistor 410 and a lower transistor 411, respectively, in the transistor structure 510 in FIG. 17A.

The transistor structure 530 differs from transistor structure 510 in that transistor structure 520: includes the metal liner in direct mechanical contact with the channel 220, and includes the silicide layer 320 above and in direct mechanical contact with the metal liner 310.

The transistor structure 530 differs from transistor structure 520 in that transistor structure 530 includes the backside contact 260.

In transistor structure 530, the metal liner 310 is between the source/drain contact 160 and the backside contact 260.

The preceding transistor structures 510, 520, 530 include the following features.

A first feature is that the upper transistor (410, 420, 430) and the lower transistor (411, 421, 431) have a shared gate 120. In one embodiment, the upper transistor is a nanosheet (NS) transistor and the lower transistor is a two-dimensional (2D) channel transistor.

A second feature is that the backside contacts (250, 260) in the lower transistor (411, 431) are each electrically and mechanically isolated from the source/drain regions (i.e., epitaxial layers 81 and 82) of the upper transistor (410, 430).

A third feature is that the backside contacts 250 and 260 of the lower transistor (411, 431) directly contact opposite ends of the channel 220.

A fourth feature is that the metal liner 310 is disposed between, and is in direct contact with, the channel and the silicide layer, and wherein the silicide layer is disposed between, and in direct contact with, the metal liner and a bottom surface of the first epitaxial layer The transistor structures 510, 520 and 530 are characterized by the following additional features in terms of reference numerals identified in FIGS. 17A, 17B and 17C and other Figures.

The transistor structures (510, 520 and 530) each comprise: an upper transistor (410, 420, 430) and a lower transistor (411, 421, 431). The upper transistor (410, 420, 430) comprises a gate (120). The gate (120) comprises a lower portion (123) and an upper portion (121 and 122). The lower transistor (411, 421, 431) comprises the lower portion (123) of the gate (120) and does not comprise the upper portion (121 and 122) of the gate (120).

The lower transistor (411, 421, 431) comprises a channel (220). A middle portion (221) of the channel (220) is in direct mechanical contact with the lower portion (123) of the gate (120).

The channel (220) is electrically and mechanically isolated from source/drain regions (81, 82) of the upper transistor (410, 420, 430).

The lower transistor (411, 421, 431) comprises a backside contact (250), a first insulating layer (70), and a second insulating layer (240). A first end portion of the channel (220) is disposed between, and in direct mechanical contact with, the backside contact (250) and a first portion of the first insulating layer (70). The second insulating layer (240) is in direct mechanical contact with the backside contact (250) and the middle portion (221) of the channel (220).

The transistor structure (510, 520, 530) comprises an epitaxial layer (82) which includes an upper portion (82A) and a lower portion (82B). The upper portion (82A) of the epitaxial layer (82) is in direct mechanical contact with a source/drain contact (160) of the upper transistor (410, 420, 430).

For the transistor structure 510, the lower transistor 411 comprises a backside contact (260). The second insulating layer (240) is in direct mechanical contact with the backside contact (260) and is disposed between the backside contact (250) and the backside contact (260). A second portion of the first insulating layer (70) is disposed between, and is in direct mechanical contact with, the channel (220) and an entire bottom surface of the lower portion (82B) of the epitaxial layer (82).

For the transistor structure 530, the lower transistor 431 comprises a metal liner (310) and a silicide layer (320). The metal liner (310) is disposed between, and in direct mechanical contact with, the channel (220) and the silicide layer (320). The silicide layer (320) is disposed between, and in direct mechanical contact with, the metal liner (310) and a bottom surface of the lower portion (82B) of the epitaxial layer (82).

For the transistor structure 520, the lower transistor 421 comprises a metal liner (310) and a silicide layer (320). The metal liner (310) is disposed between, and in direct mechanical contact with, the channel (220) and the silicide layer (320). The silicide layer (320) is disposed between, and in direct mechanical contact with, the metal liner (310) and a bottom surface of the lower portion (82B) of the epitaxial layer (82). The lower transistor 421 does not comprise any backside contact other than the backside contact 250.

The transistor structures (510, 520 and 530) each comprise: a back end of line (BEOL) wiring (200) on, and in direct contact with the upper transistor (410, 420, 430); and a carrier wafer (400) on the BEOL wiring (200).

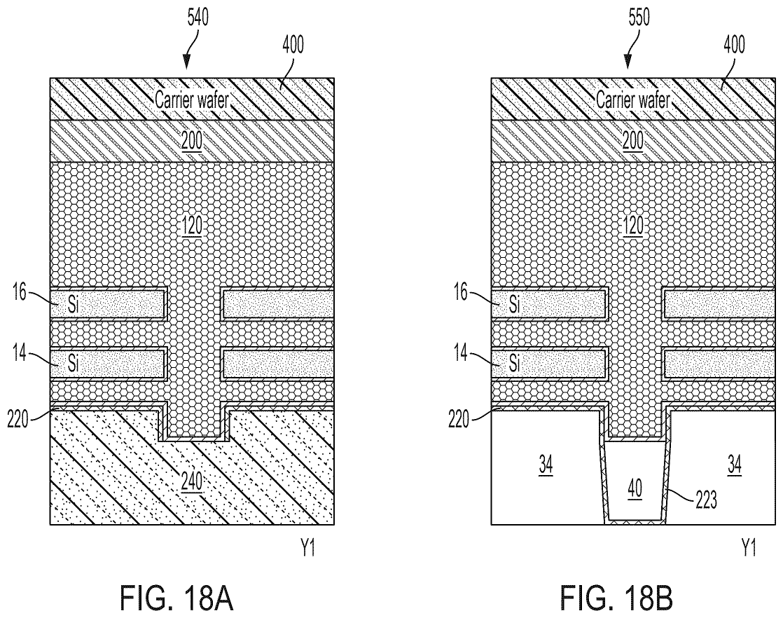

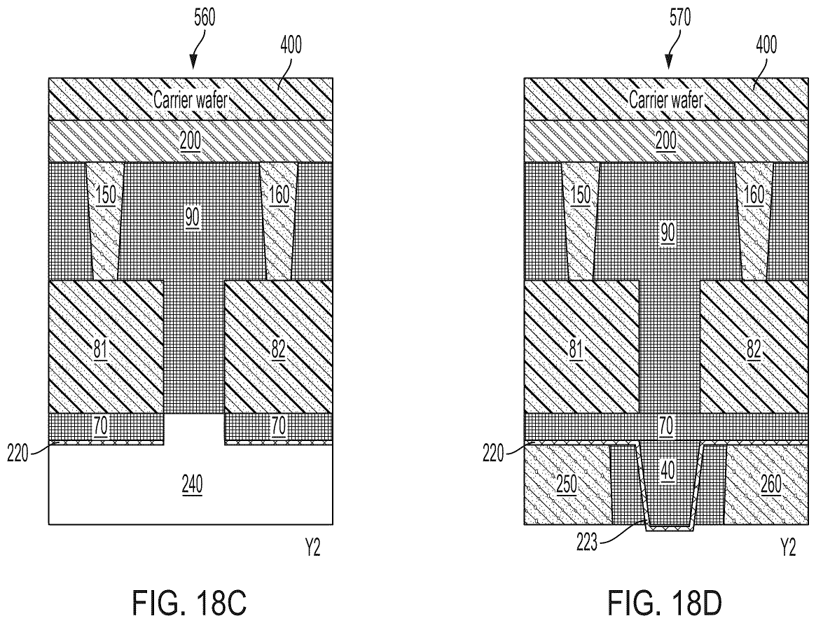

FIGS. 18A, 18B, 18C, and 18D depict intermediate structures 540, 550, 560, and 570, respectively, in accordance with embodiments of the present invention.

Intermediate structure 540 is an intermediate structure 100 depicted in the Y1 view of FIG. 15B.

In intermediate structure 540, the channel 220 is electrically disconnected, by the second insulating layer 240, from any conductive contacts below the second insulating layer 240.

Intermediate structure 550 is intermediate structure 100 depicted in the Y1 view of FIG. 13B.

In intermediate structure 550, the channel 220 is configured to be electrically connected to conductive contacts below the second insulating layer 240.

Intermediate structure 560 is intermediate structure 100 depicted in the Y2 view of FIG. 15C.

Intermediate structure 570 is formed starting with intermediate structure 100 depicted in the Y2 view of FIG. 13C, followed by adding backside contacts 250 and 260 in the same manner as backside contacts 250 and 260 are formed in FIGS. 16A-16C described supra.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A transistor structure, comprising:
an upper transistor comprising a gate, wherein the gate comprises a lower portion and an upper portion, and wherein the upper transistor is a nanosheet (NS) transistor; and
a lower transistor comprising the lower portion of the gate and not comprising the upper portion of the gate, and wherein the lower transistor is a two-dimensional (2D) channel transistor.

2. The transistor structure of claim 1, wherein the lower transistor comprises a channel, a first backside contact, and a second backside contact, wherein a middle portion of the channel is in direct contact with the lower portion of the gate, and wherein the first and second backside contacts are each electrically and mechanically isolated from both a first source/drain region of the upper transistor and a second source/drain region of the upper transistor.

3. The transistor structure of claim 2, wherein the lower transistor comprises a first insulating layer and a second insulating layer, wherein a first end portion of the channel is disposed between, and in direct contact with, the first backside contact and the first insulating layer, and wherein the second insulating layer is in direct contact with the middle portion of the channel.

4. The transistor structure of claim 3, wherein the upper transistor comprises a first epitaxial layer and a second epitaxial layer which are the first source/drain region of the upper transistor and the second source/drain region of the upper transistor, respectively, and wherein the first epitaxial layer is in direct contact with a source/drain contact of the upper transistor.

5. The transistor structure of claim 4, wherein the first insulating layer is disposed between, and is in direct contact with, the channel and a bottom surface of the first epitaxial layer.

6. The transistor structure of claim 4, wherein the lower transistor comprises a metal liner and a silicide layer, wherein the metal liner is disposed between the channel and the silicide layer, wherein the metal liner is in direct contact with the channel, and wherein the silicide layer is disposed between, and is in direct contact with, the metal liner and a bottom surface of the first epitaxial layer.

7. The transistor structure of claim 3, the second insulating layer is disposed between, and is in direct contact with, the first backside contact and the second backside contact.

8. The transistor structure of claim 1, wherein the transistor structure comprises:
a back end of line (BEOL) wiring on, and in direct contact, with the upper transistor; and
a carrier wafer on the BEOL wiring.

9. A method of forming a transistor structure, said method comprising:
forming an upper transistor and a lower transistor, said upper transistor comprising a gate, wherein the gate comprises a lower portion and an upper portion, wherein the lower transistor comprises the lower portion of the gate and does not comprise the upper portion of the gate, wherein the upper transistor is a nanosheet (NS) transistor, and wherein the lower transistor is a two-dimensional (2D) channel transistor.

10. The method of claim 9, wherein said forming the lower transistor comprises:
forming a channel, wherein the lower transistor comprises the channel, a first backside contact, and a second backside contact, wherein a middle portion of the channel is in direct contact with the lower portion of the gate, and wherein the first and second backside contacts are each electrically and mechanically isolated from both a first source/drain region of the upper transistor and a second source/drain region of the upper transistor.

11. The method of claim 10, wherein said forming the lower transistor comprises:
forming a first insulating layer and a second insulating layer, wherein the lower transistor the first insulating layer, and the second insulating layer, wherein a first end portion of the channel is disposed between, and in direct contact with, the first backside contact and the first insulating layer, and wherein the second insulating layer is in direct contact with the middle portion of the channel.

12. The method of claim 10, wherein the second insulating layer is disposed between, and is in direct contact with, the first backside contact and the second backside contact.

13. The method of claim 10, wherein said forming the upper transistor comprises:
forming a first epitaxial layer and a second epitaxial layer which are the first source/drain region of the upper transistor and the second source/drain region of the upper transistor, respectively, wherein the first epitaxial layer is in direct contact with a source/drain contact of the upper transistor.

14. The method of claim 13, wherein said forming the lower transistor comprises:
forming a metal liner and a silicide layer, wherein the lower transistor comprises the metal liner and the silicide layer, wherein the metal liner is disposed between the channel and the silicide layer, wherein the metal liner is in direct contact with the channel, and wherein the silicide layer is disposed between, and is in direct contact with, the metal liner and a bottom surface of the first epitaxial layer.

15. A transistor structure, comprising:
an upper transistor comprising a gate, wherein the gate comprises a lower portion and an upper portion, and wherein the upper transistor is a nanosheet (NS) transistor; and
a lower transistor comprising the lower portion of the gate and not comprising the upper portion of the gate, wherein the lower transistor comprises a first backside contact and does not comprise any other backside contact, and wherein the lower transistor is a two-dimensional (2D) channel transistor.

16. The transistor structure of claim 15, wherein the lower transistor comprises a channel, wherein a middle portion of the channel is in direct contact with the lower portion of the gate, and wherein the first backside contact is electrically and mechanically isolated from both a first source/drain region of the upper transistor and a second source/drain region of the upper transistor.

17. The transistor structure of claim 16, wherein the lower transistor comprises a first insulating layer and a second insulating layer, wherein a first end portion of the channel is disposed between, and in direct contact with, the first backside contact and the first insulating layer, and wherein the second insulating layer is in direct contact with the middle portion of the channel.

18. The transistor structure of claim 16, wherein the upper transistor comprises a first epitaxial layer and a second epitaxial layer which are the first source/drain region of the upper transistor and the second source/drain region of the upper transistor, respectively, and wherein the first epitaxial layer is in direct contact with a source/drain contact of the upper transistor.

19. The transistor structure of claim 18, wherein the lower transistor comprises a metal liner and a silicide layer, wherein the metal liner is disposed between the channel and the silicide layer, wherein the metal liner is in direct contact with the channel, and wherein the silicide layer is disposed between, and is in direct contact with, the metal liner and a bottom surface of the first epitaxial layer.

20. The transistor structure of claim 15, wherein the transistor structure comprises:
a back end of line (BEOL) wiring on, and in direct contact, with the upper transistor; and
a carrier wafer on the BEOL wiring.
